(19) United States
(12) Patent Application Publication
(10) Pub. No.: US 2014/0319489 A1
(43) Pub. Date: Oct. 30, 2014

(54) ORGANIC LIGHT EMITTING DEVICE AND MANUFACTURING METHOD THEREOF

(71) Applicant: EverDisplay Optronics (Shanghai) Limited, Shanghai (CN)

(72) Inventor: JuoSheng Chu, Shanghai (CN)

(73) Assignee: EverDisplay Optronics (Shanghai) Limited, Shanghai (CN)

(21) Appl. No.: 14/258,897

(22) Filed: Apr. 22, 2014

(30) Foreign Application Priority Data
Apr. 25, 2013 (CN) 201310148123.5

(51) Int. Cl. H01L 27/32; H01L 51/56

(52) U.S. Cl. CPC H01L 27/3227; H01L 51/56
USPC 257/40; 438/25

(57) ABSTRACT

The present disclosure provides an organic light emitting device and a manufacturing method thereof. When the photovoltaic units are the integrated above the OLED unit, the photovoltaic units are transparent solar panels; when the photovoltaic units are integrated under the OLED unit, the photovoltaic units are gallium arsenide solar panels. By means of integrating a plurality of photovoltaic units are integrated into the organic light emitting devices, the present disclosure possesses functions of the transformation of electrical energy from luminous energy and the storage of the electrical energy in the photovoltaic units, i.e., the present disclosure is self powdered without any external power supply. Therefore, the present disclosure can achieve the environmental protection and the energy saving, as well as small volume, light weight and high integration level.

### CROSS-REFERENCE TO RELATED APPLICATIONS

The present application claims priority to and the benefit of Chinese Patent Application No. CN 201310148123.5, filed on Apr. 25, 2013, the entire content of which is incorporated herein by reference.

### BACKGROUND OF THE INVENTION

1. Field of the Invention

The present disclosure relates to the technology for manufacturing the organic photoelectric device, more specifically, to an organic light emitting device and a manufacturing method thereof

2. Description of the Related Art

In the field of organic photoelectricity, Organic Light Emitting Diode and Organic Solar Battery are the research focus. The two technologies are illustrated in the following content.

The Organic Light Emitting Diode (“OLED”, hereinafter) is also called Organic Electroluminesence Display. It developed an organic electroluminesence device with low driving voltage by using a small molecular organic compound Alq3. The organic electroluminesence shows a very great vitality because of its advantages such as low driving voltage, highly luminance, active electroluminesence, easiness to realize the monochromatic or color flat display, simple manufacturing process, completely solidification and low power consumption. The common structure of the Organic Light Emitting Diode includes: a substrate, an Indium Tin Oxide (“ITO”, hereinafter) Anode, a Hole Injection Layer, a Hole Transport Layer, an Emitting Layer, an Electron Transport Layer, an Electron Injection layer and a Cathode. The holes and electrons are injected from the Anode and Cathode separately, passing through the Hole Transport Layer and the Electron Transport Layer, to interact to form excitons in the Emitting Layer. The excitons emit lights by deexcitation.

The Organic Solar Battery is one type of the solar battery, the core part of which is composed of organic materials. The first organic photoelectric converting device is manufactured by Kearns and Calvin in 1958. The main material is Magnesium Phthalocyanine (“MgPc”, hereinafter) dye in the middle of two deposition layer with different work functions. Double layer heterojunction solar battery founded in 1986, the double layer of which is composed of a derivative of perylene tetracarboxylic acid and Copper Phthalocyanine (“CuPc”, hereinafter) can achieve an efficiency of 1%. The structure of the double layer heterojunction solar battery includes: the organic semiconductor material donor and the organic semiconductor material receptor, wherein electron-hole pairs are generated after the receptor materials absorbing photons. After the electrons are injected into the organic semiconductor material receptor, the holes and electrons are separated and output from electrode to form photocurrent. Now, the heterojunction solar battery is still the research focus. Later, bulkhetero-junction is advanced, wherein, the receptor material and donor materials are mixed to form a layer of film by means of co-stewing or spin-coating process. Therefore, the excitons generated anywhere can be easy to reach the interface between the donor and the receptor to increase the efficiency of charges separation.

In the related art, the organic solar battery and organic electroluminesence diode are generally integrated by stack or cascade to achieve the transformation of electric energy from luminous energy and the storage of the electric energy. Meanwhile, the organic electroluminesence diode can achieve the self-power without the external power supply and can achieve the environmental protection and the energy saving. However, the primitive integration by means of the stack or the cascade will enlarge volume, be against to the widely use and increase of the integration level. Meanwhile the primitive integration will add the weight of the device and, therefore, will badly impact the work life of the device.

### SUMMARY OF THE INVENTION

An aspect of an embodiment of the present disclosure is directed toward manufacturing method of the organic light emitting device capable of saving the energy and protecting the environment.

Another aspect of an embodiment of the present disclosure is directed toward an organic light emitting device capable of smaller the volume thereof, lightening the weight thereof and improving the integration level.

An embodiment of the present disclosure provides a manufacturing method of an organic light emitting device comprising:

(a) providing the organic light emitting device including an OLED unit; and

(b) integrating a plurality of photovoltaic units above or under the OLED unit of the organic light emitting device.

According to one embodiment of the present disclosure, wherein the photovoltaic units are integrated above the OLED unit and the photovoltaic units are transparent solar panels.

According to one embodiment of the present disclosure, wherein the photovoltaic units are integrated under the OLED unit and the photovoltaic units are gallium arsenide solar panels.

According to one embodiment of the present disclosure, wherein the OLED unit includes a first electrode layer, an OLED layer and a second electrode layer;

wherein, the upper surface of the second electrode layer is covered by the OLED layer and the upper surface of the OLED layer is covered by the first electrode layer.

According to one embodiment of the present disclosure, wherein the first electrode layer is an indium tin oxide anodic layer and the second electrode layer is a metal cathode layer.

Another embodiment of the present disclosure provides an organic light emitting device, comprising:

an OLED unit; and

a plurality of photovoltaic units located above or under the OLED unit.

According to another embodiment of the present disclosure, wherein the photovoltaic units are integrated above the OLED unit and the photovoltaic units are transparent solar panels.

According to another embodiment of the present disclosure, wherein the photovoltaic units are integrated under the OLED unit and the photovoltaic units are gallium arsenide solar panels.

According to another embodiment of the present disclosure, wherein the organic light emitting device also includes a protecting layer located above the OLED unit.

According to another embodiment of the present disclosure, wherein the photovoltaic units are integrated on a lower surface of the protecting layer, or on an upper surface of the OLED unit or on the lower surface of the OLED unit.

According to another embodiment of the present disclosure, wherein the organic light emitting device also includes a color filtrating layer located between the protecting layer and the OLED unit; the photovoltaic units are integrated on an upper surface or a lower surface of the color filtrating layer.

According to another embodiment of the present disclosure, wherein the color filtrating layer is a color filter.

According to another embodiment of the present disclosure, wherein the organic light emitting device also includes a TFT layer located under the OLED unit; the photovoltaic units are integrated on an upper surface of the TFT layer.

According to another embodiment of the present disclosure, wherein the organic light emitting device also includes a substrate; the TFT layer is located above the substrate.

According to another embodiment of the present disclosure, wherein the substrate is a glass substrate or a plastic substrate.

According to another embodiment of the present disclosure, wherein the OLED unit comprises a first electrode layer, an OLED layer and a second electrode layer;

the upper surface of the second electrode layer is covered by the OLED layer; the upper surface of the OLED is covered by the first electrode layer.

According to another embodiment of the present disclosure, wherein the first electrode layer is an indium tin oxide anodic layer and the second electrode layer is a metal cathode layer.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a structure diagram of the photovoltaic units integrated on the lower surface of the protecting layer in Embodiment 1 of the present disclosure;

FIG. 2 shows a structure diagram of the photovoltaic units integrated on the upper surface of the color filtrating layer in Embodiment 2 of the present disclosure;

FIG. 3 shows a structure diagram of the photovoltaic units integrated on the lower surface of the color filtrating layer in Embodiment 3 of the present disclosure;

FIG. 4 shows a structure diagram of the photovoltaic units integrated on the upper surface of OLED unit in Embodiment 4 of the present disclosure;

FIG. 5 shows a structure diagram of the photovoltaic units integrated on the lower surface of OLED unit in Embodiment 5 of the present disclosure;

FIG. 6 shows a structure diagram of the photovoltaic units integrated on the upper surface of on TFT in Embodiment 6 of the present disclosure.

### DETAILED DESCRIPTIONS

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms, including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

### Embodiment 1

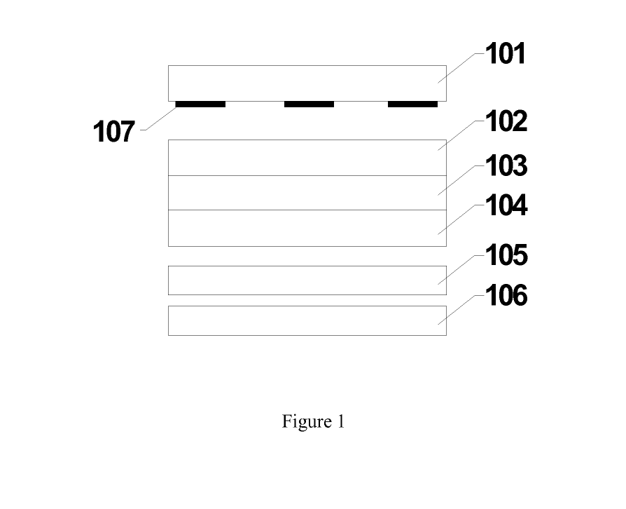

FIG. 1 shows the structure diagram of the photovoltaic units integrated on the lower surface of the protecting layer in this embodiment. As shown in FIG. 1, the organic light-emitting device, such as Active Matrix Organic Light-Emitting Diode (“AMOLED”, hereinafter), includes: a Protecting Layer 101, an ITO Anode Layer 102, an OLED Layer 103, a Metal Cathode Layer 104, a TFT Layer 105 and a Substrate 106. A plurality of Photovoltaic Units 107, which are transparent solar panels for obtaining the high efficient conversion rate, are integrated on the lower surface of Protecting Layer 101. ITO Anode Layer 102, OLED Layer 103 and Mental Cathode Layer 104 together constitute an OLED unit. Preferably, Substrate 106 can be a rigid substrate, such as the glass substrate or plastic substrate.

### Embodiment 2

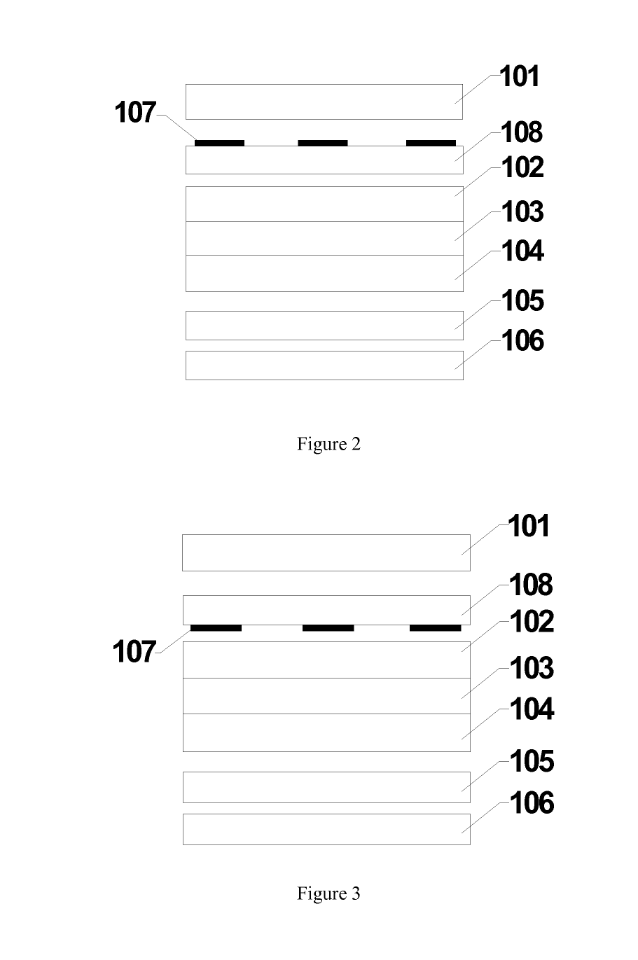

FIG. 2 shows the structure diagram of the photovoltaic units integrated on upper surface of the color filtrating layer in this embodiment. As shown in FIG. 2, the organic light emitting device, such as AMOLED, includes: a Protecting Layer 101, a Color Filtrating Layer 108, an ITO Anode Layer 102, an OLED Layer 103, a Metal Cathode Layer 104, a TFT Layer 105 and a Substrate 106. A plurality of Photovoltaic Units 107, which are transparent solar panels for obtaining the high efficient conversion rate, are integrated on the upper surface of Color Filtrating Layer 108, such as a color filter. ITO Anode Layer 102, OLED Layer 103 and Mental Cathode Layer 104 together constitute an OLED unit. Preferably, Substrate 106 can be a rigid substrate, such as the glass substrate or plastic substrate.

### Embodiment 3

FIG. 3 shows the structure diagram of the photovoltaic units integrated on lower surface of the color filtrating layer in this embodiment. As shown in FIG. 3, the organic light emitting device, such as AMOLED, includes: a Protecting Layer 101, a Color Filtrating Layer 108, an ITO Anode Layer 102, an OLED Layer 103, a Metal Cathode Layer 104, a TFT Layer 105 and a Substrate 106. A plurality of Photovoltaic Units 107, which are transparent solar panels for obtaining the high efficient conversion rate, are integrated on the lower surface of Color Filtrating Layer 108, such as a color filter. ITO Anode Layer 102, OLED Layer 103 and Mental Cathode Layer 104 together constitute an OLED unit. Preferably, Substrate 106 can be a rigid substrate, such as the glass substrate or plastic substrate.

### Embodiment 4

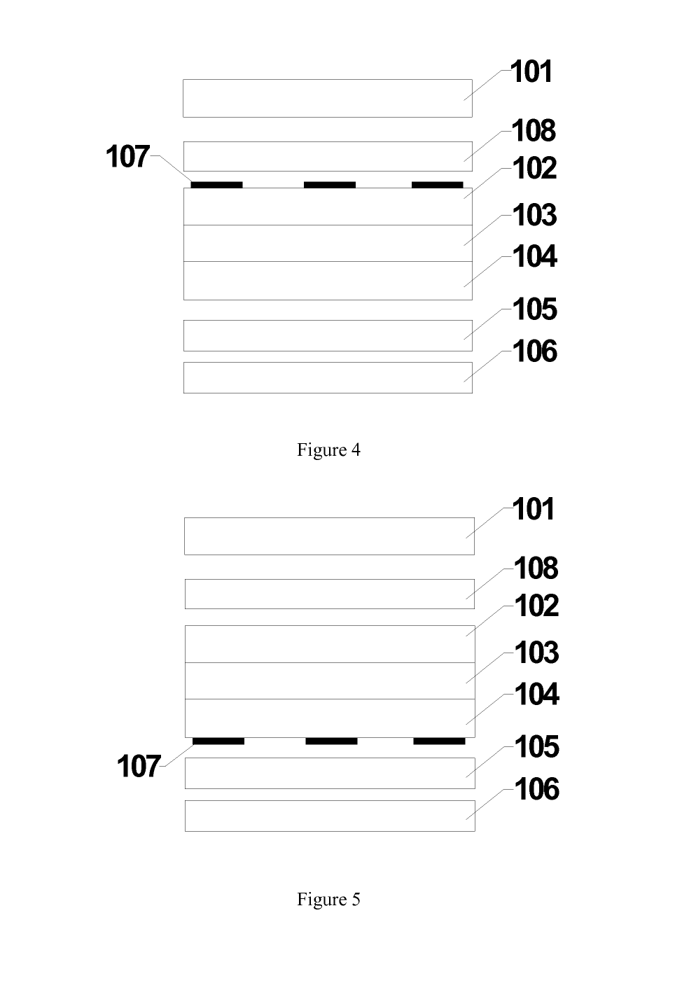

FIG. 4 shows the structure diagram of the photovoltaic units integrated on upper surface of the OLED unit in this embodiment. As shown in FIG. 4, the organic light emitting device, such as AMOLED, includes: a Protecting Layer 101, a Color Filtrating Layer 108, an ITO Anode Layer 102, an OLED Layer 103, a Metal Cathode Layer 104, a TFT Layer 105 and a Substrate 106. A plurality of Photovoltaic Units 107, which are transparent solar panels for obtaining the high efficient conversion rate, are integrated on the upper surface of the OLED unit constituted by ITO Anode Layer 102, OLED Layer 103 and Mental Cathode Layer 104 together. Preferably, Color Filtrating Layer 108 can be a color filter. Preferably, Substrate 106 can be a rigid substrate, such as the glass substrate or plastic substrate.

Furthermore, in this embodiment, AMOLED can not include Color Filtrating Layer 108. And Photovoltaic Units 107, which are transparent solar panels for obtaining the high efficient conversion rate, are integrated on the upper surface of ITO Anode Layer 102.

### Embodiment 5

FIG. 5 shows the structure diagram of the photovoltaic units integrated on lower surface of the OLED unit in this embodiment. As shown in FIG. 5, the organic light emitting device, such as AMOLED, includes: a Protecting Layer 101, a Color Filtrating Layer 108, an ITO Anode Layer 102, an OLED Layer 103, a Metal Cathode Layer 104, a TFT Layer 105 and a Substrate 106. A plurality of Photovoltaic Units 107, which are gallium arsenide solar panels for obtaining the high efficient conversion rate, are integrated on the lower surface of the OLED unit constituted by ITO Anode Layer 102, OLED Layer 103 and Mental Cathode Layer 104 together. Preferably, Color Filtrating Layer 108 can be a color filter. Preferably, Supporting Base 106 can be a rigid substrate, such as the glass substrate or plastic substrate.

Furthermore, in this embodiment, AMOLED can not include Color Filtrating Layer 108. And Photovoltaic Units 107, which are gallium arsenide solar panels for obtaining the high efficient conversion rate, are integrated on the lower surface of Mental Cathode Layer 104.

### Embodiment 6

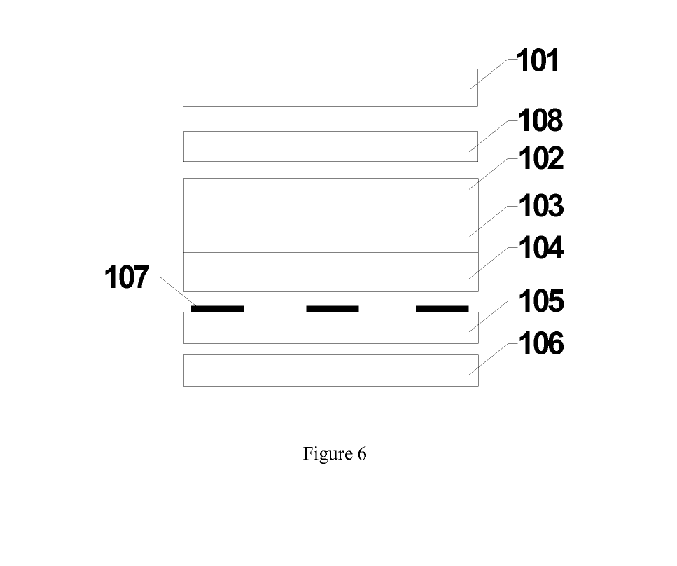

FIG. 6 shows the structure of the photovoltaic units integrated on upper surface of the TFT layer in this embodiment. As shown in FIG. 6, the organic light emitting device, such as AMOLED, includes: a Protecting Layer 101, a Color Filtrating Layer 108, an ITO Anode Layer 102, an OLED Layer 103, a Metal Cathode Layer 104, a TFT Layer 105 and a Substrate 106. A plurality of Photovoltaic Units 107, which are gallium arsenide solar panels for obtaining the high efficient conversion rate, are integrated on the upper surface of TFT Layer 105. Preferably, Color Filtrating Layer 108 can be a color filter. ITO Anode Layer 102, OLED Layer 103 and Mental Cathode Layer 104 together constituted the OLED unit. Preferably, Substrate 106 can be a rigid substrate, such as the glass substrate or plastic substrate.

Furthermore, in this embodiment, AMOLED can not include Color Filtrating Layer 108. And Photovoltaic Units 107, which are gallium arsenide solar panels for obtaining the high efficient conversion rate, are integrated on the upper surface of TFT Layer 105.

By means of any structure of the above-mentioned embodiments, the present disclosure overcomes the problems, such as large volume and low integration level, caused by stack or cascade in the related art. Meanwhile the device manufactured in this embodiment possesses functions of transforming the luminous energy to the electrical energy and storing the electric energy, i.e., AMOLED is self powered without the external power supply. Therefore, the present disclosure achieves the environmental protection and the energy saving, as well as small volume, light weight and high integration level.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof

What claimed is:

1. A manufacturing method of an organic light emitting device comprising:
(a) providing the organic light emitting device including an OLED unit; and
(b) integrating a plurality of photovoltaic units above or under the OLED unit of the organic light emitting device.

2. The manufacturing method as claimed in claim 1, wherein the photovoltaic units are integrated above the OLED unit and the photovoltaic units are transparent solar panels.

3. The manufacturing method as claimed in claim 1, wherein the photovoltaic units are integrated under the OLED unit and the photovoltaic units are gallium arsenide solar panels.

4. The manufacturing method as claimed in claim 3, wherein the OLED unit includes a first electrode layer, an OLED layer and a second electrode layer;
wherein, the upper surface of the second electrode layer is covered by the OLED layer and the upper surface of the OLED layer is covered by the first electrode layer.

5. The manufacturing method as claimed in claim 4, wherein the first electrode layer is an indium tin oxide anodic layer and the second electrode layer is a metal cathode layer.

6. An organic light emitting device, comprising:
an OLED unit; and
a plurality of photovoltaic units located above or under the OLED unit.

7. The organic light emitting device as claimed in claim 6, wherein the photovoltaic units are integrated above the OLED unit and the photovoltaic units are transparent solar panels.

8. The organic light emitting device as claimed in claim 6, wherein the photovoltaic units are integrated under the OLED unit and the photovoltaic units are gallium arsenide solar panels.

9. The organic light emitting device as claimed in claim 6, wherein the organic light emitting device also includes a protecting layer located above the OLED unit.

10. The organic light emitting device as claimed in claim 9, wherein the photovoltaic units are integrated on a lower surface of the protecting layer, or on an upper surface of the OLED unit or on the lower surface of the OLED unit.

11. The organic light emitting device as claimed in claim 9, wherein the organic light emitting device also includes a color filtrating layer located between the protecting layer and the OLED unit; the photovoltaic units are integrated on an upper surface or a lower surface of the color filtrating layer.

12. The organic light emitting device as claimed in claim 11, wherein the color filtrating layer is a color filter.

13. The organic light emitting device as claimed in claim 6, wherein the organic light emitting device also includes a TFT layer located under the OLED unit; the photovoltaic units are integrated on an upper surface of the TFT layer.

14. The organic light emitting device as claimed in claim 13, wherein the organic light emitting device also includes a substrate; the TFT layer is located above the substrate.

15. The organic light emitting device as claimed in claim 14, wherein the substrate is a glass substrate or a plastic substrate.

16. The organic light emitting device as claimed in claim 15, wherein the OLED unit comprises a first electrode layer, an OLED layer and a second electrode layer;
the upper surface of the second electrode layer is covered by the OLED layer; the upper surface of the OLED is covered by the first electrode layer.

17. The organic light emitting device as claimed in claim 16, wherein the first electrode layer is an indium tin oxide anodic layer and the second electrode layer is a metal cathode layer.
